(19) United States
(12) Patent Application Publication
(10) Pub. No.: US 2014/0211534 A1
(43) Pub. Date: Jul. 31, 2014

(54) LOCALLY ACTIVE MEMRISTIVE DEVICE

(71) Applicant: HEWLETT-PARKARD DEVELOPMENT COMPANY, L.P., Houston, TX (US)

(72) Inventors: Matthew D. Pickett, San Francisco, CA (US); R. Stanley Williams, Portola Valley, CA (US)

(73) Assignee: Hewlett-Parkard Development Company, L.P., Houston, TX (US)

(21) Appl. No.: 13/753,511

(22) Filed: Jan. 29, 2013

(51) Int. Cl. G11C 13/00

(52) U.S. Cl. CPC G11C 13/0002
USPC 365/148

(57) ABSTRACT

A method to operate an integrated circuit includes operating a locally active memristive device in a locally reactive region of an operating domain where the device exhibits inductor-like behavior, such as a phase shift where a voltage across the device leads a current through the device.

### BACKGROUND

Reactive elements are used in a wide variety of applications including impedance matching networks and filters. One challenge for integrated fabrication of reactive elements is their poor scaling properties, especially for inductors. Inductors can be integrated or emulated with a conventional complementary metal-oxide-semiconductor (CMOS) process or a microelectromechanical systems (MEMS)-specific process but their size tends to be on the order of a square millimeters to get minimally useful inductances.

### BRIEF DESCRIPTION OF THE DRAWINGS

In the drawings:

FIG. 1 is a side cross-sectional view of a locally active memristive device implemented as a vertical device in one example of the present disclosure;

FIG. 2 is a side cross-sectional view of the locally active memristive device implemented as a lateral device in one example of the present disclosure.

FIG. 3 is a flowchart of a method to operate the device of FIG. 1 or 2 in one example of the present disclosure;

FIG. 4 is a simulated response of a model of the device of FIG. 1 driven by a periodic input signal in one example of the present disclosure;

FIG. 5 is circuit diagram of an integrated circuit including a locally active memristive device in one example of the present disclosure;

FIG. 6 is a cross-sectional view of a semiconductor structure of the integrated circuit including the locally active memristive device of FIG. 3 in one example of the present disclosure; and

FIG. 7 is an S-shaped current-voltage curve of the device of FIG. 1 in one example of the present disclosure.

Use of the same reference numbers in different figures indicates similar or identical elements.

### DETAILED DESCRIPTION

As used herein, the term “includes” means includes but not limited to, the term “including” means including but not limited to. The terms “a” and “an” are intended to denote at least one of a particular element. The term “based on” means based at least in part on.

A memristive device is a passive two-terminal device that has a dynamic relationship between the time integral of current and the time integral of voltage. For a memristive device, resistance depends on the integral of the input applied to the terminals.

In examples of the present disclosure, a locally active memristive device is operated in a region of its operating domain where the device exhibits inductor-like behavior, such as a phase shift where the voltage across the device leads the current through the device. The phase shift indicates the device has a positive reactance or, equivalently, an effective inductance in the “locally reactive region” of its operating domain. The device may be used for densely integrated filters, impedance matching networks, phase shifters, antennas, or another inductive application that does not involve a true inductance having energy storage.

In one example, the inductor-like behavior is achieved with a two-terminal device that exhibits current-controlled negative differential resistance (CC-NDR). The phenomenon of CC-NDR is also known as “threshold switching” due to the existence of bi-stable low and high resistance states under voltage or current bias as well as “S-shaped NDR” because of the S-like shape of the current-voltage curve. In one example, the device is a two-terminal metal-insulator-metal device that exhibits a temperature-driven insulator-to-metal phase transition. The threshold switching in the device may be volatile where the switching effect disappears as current is removed from the device.

In one example, the device is excited with a periodic input signal that has a period and a magnitude based on switching times and switching current of the device. In response, the device exhibits a reliable lag between voltage and current so the device resembles an inductor in the locally reactive region of its operating domain.

As a nanoscale device, a locally active memristive device provides several orders of magnitude improvement of effective inductance per unit area over prior approaches. However, the device is dissipative as it does not store energy like an inductor, it is limited to certain operating frequencies and magnitudes, and it is lossy (having a phase shift<π/2).

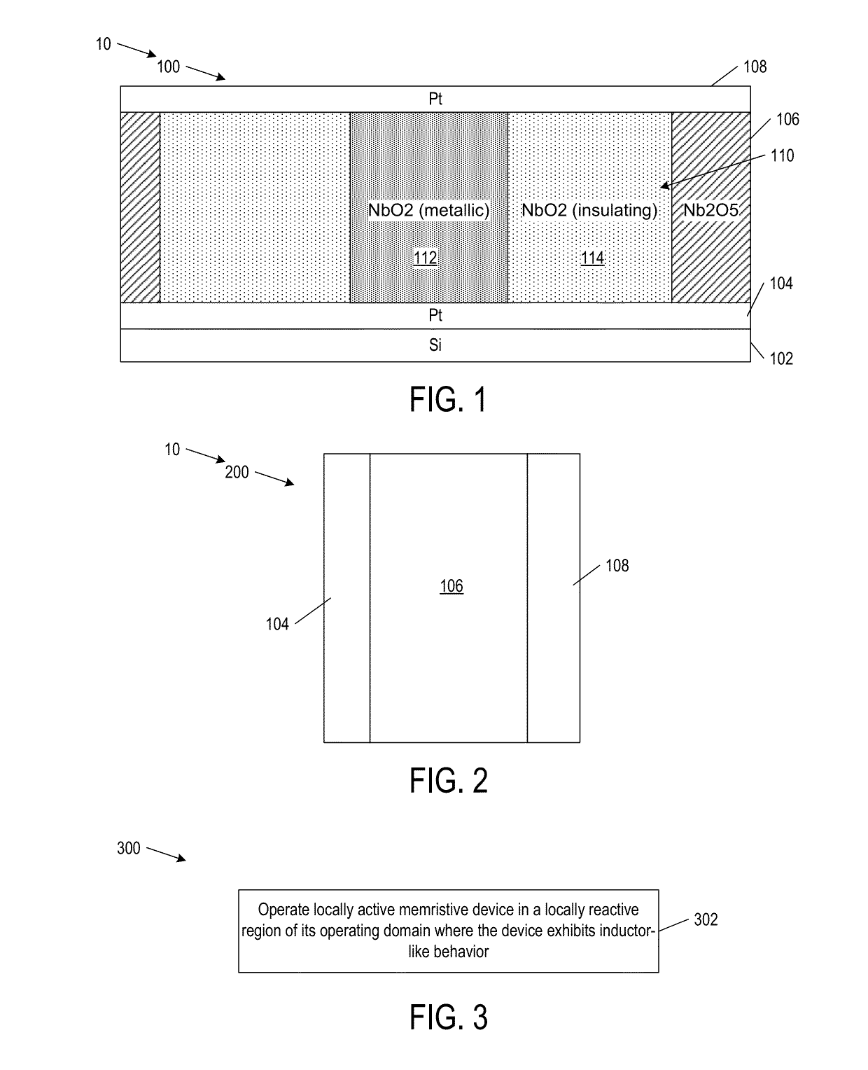

FIG. 1 is a side cross-sectional view of a locally active memristive device 10 implemented as a vertical device 100 in one example of the present disclosure. Device 100 may be an S-shaped NDR device. Device 100 includes a substrate 102 and a bottom electrode 104 patterned on the substrate. Substrate 102 may be a silicon (Si) wafer with a 200 nanometer (nm) thick thermally grown oxide. Bottom electrode 104 may be 110 nm wide. Bottom electrode 104 may include a 2 nm thick titanium (Ti) adhesion layer and a 9 nm thick platinum (Pt) conduction layer. An insulator 106 is deposited over bottom electrode 104. Insulator 106 is a transition metal oxide that exhibits a temperature-driven insulator-to-metal phase transition. When heated, insulator 106 may transition from an insulating phase to a metallic phase, thereby changing device 100 from a high resistance (OFF) state to a low resistance (ON) state. When the current is turned off, insulator 106 mat transition from the metallic phase back to the insulating phase, thereby changing device 100 from the ON state back to the OFF state. In one example insulator 106 is niobium oxide (Nb₂O₅) deposited by reactively sputtering a metallic Nb target with a gas mixture of 1/5: oxygen (O₂)/argon (Ar) at 5 millitorr (mTorr). A top electrode 108 is patterned on insulator 106 to cross perpendicular to bottom electrode 104. Top electrode 108 may be 110 nm wide so the device area is 110 by 110 nm². Top electrode 108 may be a 11 nm thick Pt conduction layer. In one example where insulator 106 is Nb₂O₅, a 6 volt (V), 10 microsecond (μs) electroforming pulse is used to modify the low-bias resistance of device 100 from a 10 gigaohm (GΩ) virgin state to a 1 megaohm (MΩ) operational regime. The electroforming creates a channel 110 of crystalline NbO₂ that exhibits insulator-to-metal transition at 1080 kelvin (K) within the oxide film, which is graphically illustrated by metallic region 112 and an insulating region 114. For other materials, electroforming may or may not be used.

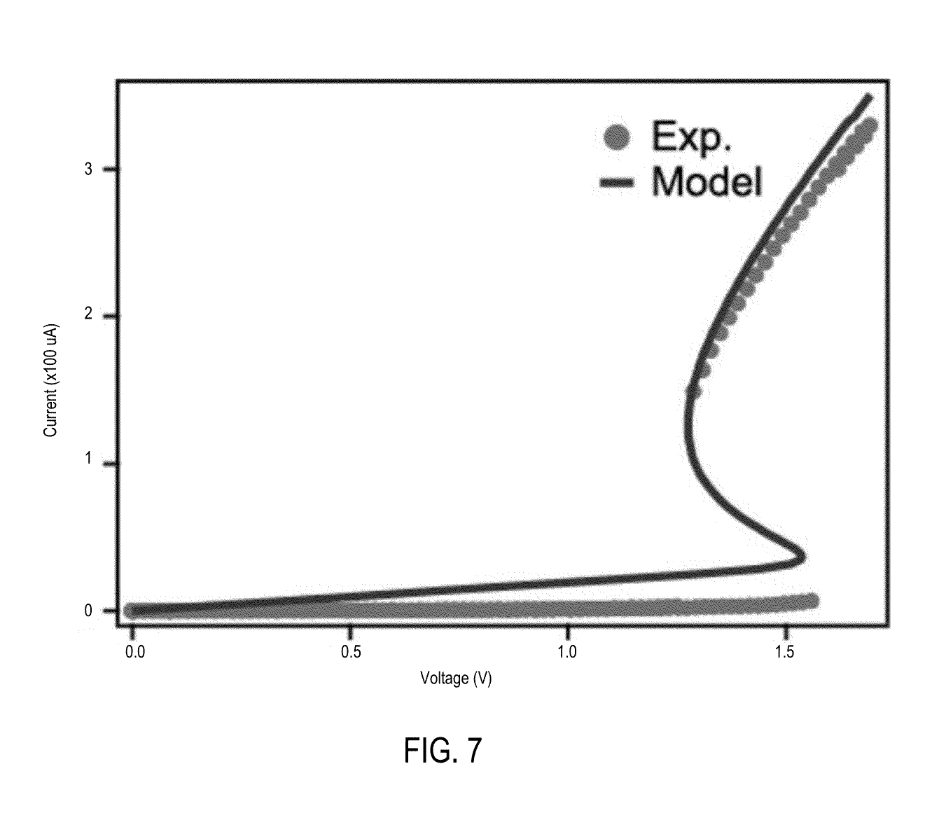

Device 100 transitions between the OFF state and the ON state when it is driven to its instability points, also referred to as the “switching thresholds,” located at the two inflection points of the S-curve of the device. FIG. 7 illustrates an S-shaped current-voltage curve of device 100 in one example of the present disclosure. It takes a certain amount of time (“switching time Δt_{ON}”) for device 100 to switch from the ON state to the OFF state, and it takes a certain amount of time (“switching time Δt_{OFF}”) for the device to switch from the OFF state back to the ON state. In one example, device 100 has a switching time Δt_{ON} of approximately 700 picoseconds (ps) and a switching time Δt_{OFF} of approximately 2.3 nanoseconds (ns), which sums to a total switching time of approximately 3 ns. Device 100 switches between the ON and the OFF states in a range of switching currents between i_{ON} and i_{OFF} located at the inflection points on the S-curve of the device. In one example, device 100 has a range of switching currents between 20 and 150 microamps (μA).

Although an example of device 100 utilizing a transition metal oxide is provided herein, the present disclosure may be implemented with other S-shaped NDR devices having different materials and physical mechanisms that govern the behavior of the device. Other two-terminal devices are known to exhibit S-shape NDR by using other transition metal oxides, organic materials, chalcogenide semiconductors, silicon nanowires, and Wigner solids.

Locally active memristive device 10 may also be implemented as a lateral device. FIG. 2 is a top plan view of locally active memristive device 10 implemented as a lateral device 200 in one example of the present disclosure. Device 200 has similar structure and function as device 100 (FIG. 1) so similar elements share the same reference numbers between devices 100 and 200.

FIG. 3 is a method to operate an integrated circuit including device 10 (FIG. 1 or 2) in one example of the present disclosure. Method 300 may begin in block 302.

In block 302, device 10 (e.g., vertical device 100) is operated in a locally reactive region of its operating domain where device 100 exhibits inductor-like behavior. In one example, the inductor-like behavior includes a phase shift where the voltage across the device leads the current through the device. In one example, device 100 is operated with a periodic input signal having a period p based on switching times Δt_{ON}, Δt_{OFF} of the device and a magnitude m (between peak and valley of the signal) based on the switching currents of the device. The periodic input signal may be an input voltage or an input current. Period p may be within a factor of five of the sum of switching times Δt_{ON} and Δt_{OFF} (e.g., p≦5(Δt_{ON}+Δt_{OFF})). Magnitude m may be within ±10% of the switching current range (e.g., 0.9i_{ON}≦m≦1.1i_{OFF}). In one example, the periodic input signal includes a voltage or current offset that drives and maintains device 100 about the switching threshold of the ON state. In one example, the offset for an input voltage is 1 V. In one example, the offset for an input current is 20 μA. Alternatively an offset signal is provided to device 100 separately from the periodic input signal.

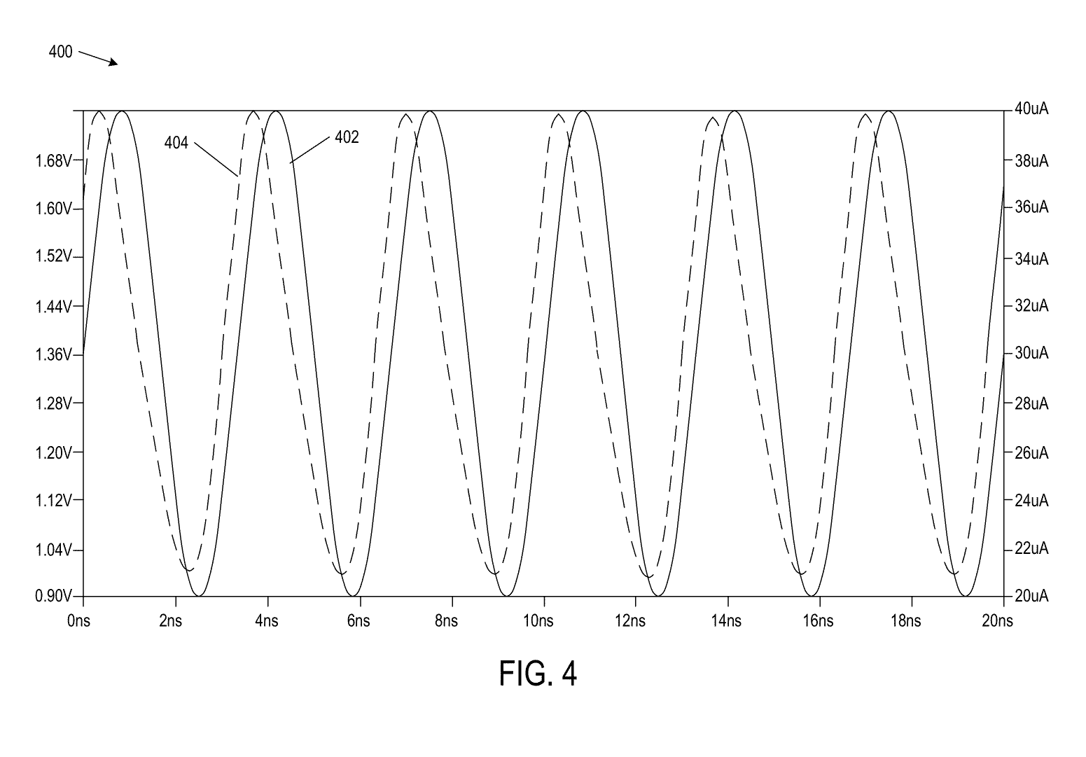

FIG. 4 is a chart 400 of a simulated response of device 10 (FIG. 1) to a periodic input signal in one example of the present disclosure. In one example, the periodic input signal is a current signal 402. Current signal 402 has a period of p of approximately 3. 3̅ ns (or a frequency f of 0.3 gigahertz (GHz)) based on a total switching time of 3 ns. Current signal 402 has a magnitude of approximately 20 μA based on the switching current range of 20 to 150 μA. In one example, the periodic input signal is a voltage signal 404. Voltage signal 404 has a period p of approximately 3. 3̅ ns based on a total switching time of 3 ns. Voltage signal 404 has a magnitude m of approximately 0.76 V, which causes current signal 402 to have a magnitude of 20 μA that is commensurate with a switching current range between 20 and 150 μA.

As can be seen, voltage waveform 404 leads current waveform 402 by about π/4 (45 degrees), which indicates a complex impedance with a positive reactance. Fitting voltage waveform 404 yields an impedance of Z=27+25i kiloohms (kΩ). With a frequency of 0.3 GHz for the periodic input signal, the reactance of the impedance yields an effective inductance of 14 microhenry (μH) or 130 kilohenry (kH)/centimeter² (cm²). In contrast, an all-metal 1 by 1 millimeter² (mm²) integrated (on-chip) spiral inductor have an inductance on the order of 30 nanohenry (nH) or 10 μH/cm². Note this is not a direct comparison as the spiral inductor stores power whereas device 10 does not.

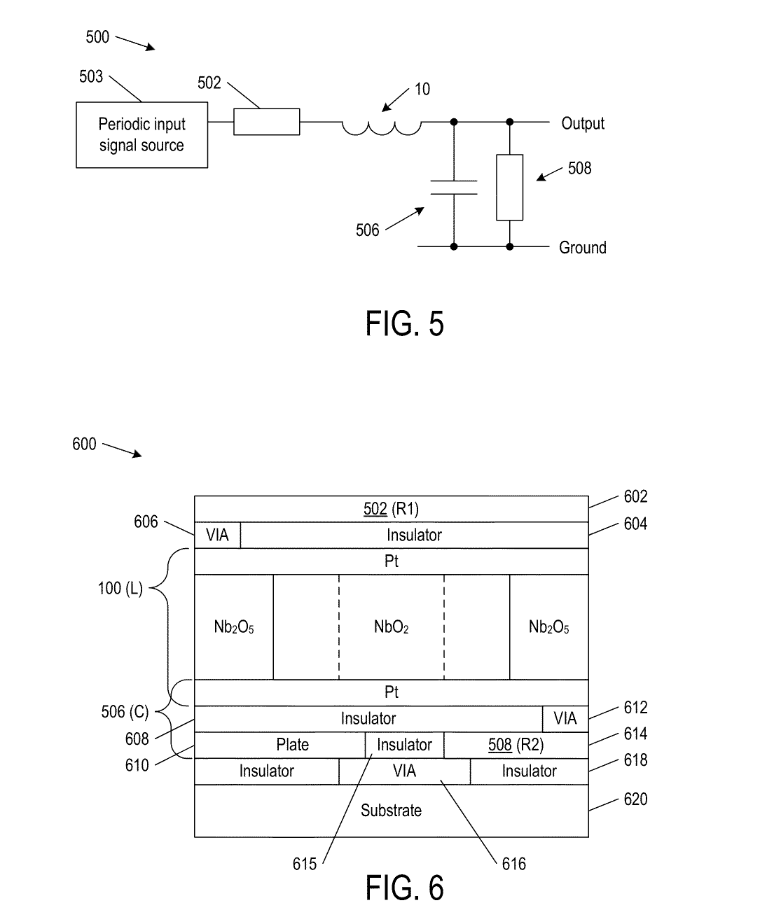

FIG. 5 is circuit diagram of an integrated circuit (IC) 500 including device 10 (FIG. 1) in one example of the present disclosure. IC 500 may be a low-pass filter. IC 500 includes a resistor 502 having a first terminal that receives a periodic input signal, which may be generated by another circuit having electronic components represented by block 503. Device 10 (FIG. 1 or 2) has a first terminal coupled to the second terminal of resistor 502. A capacitor 506 and a resistor 508 have their first terminals coupled in parallel to the second terminal of device 10. Capacitor 506 and resistor 508 have their second terminals grounded.

In one example, IC 500 may be designed with a layout tool. The layout tool determines the structure of device 10 based on a given inductance and frequency range desired by a particular application.

IC 500 may include other components, passive or active. Device 10 may also be included in other circuits such as an impedance matching network, an antenna, or another IC that utilizes a locally active device with inductor-like behavior.

FIG. 6 is a side cross-sectional view of a semiconductor structure 600 of IC 500 (FIG. 5) including device 100 (FIG. 1) in one example of the present disclosure. Structure 600 includes a conduction layer 602 patterned to form resistor 502. A via 606 is formed through an insulator 604 and filled with a metal to couple resistor 502 to device 100. An insulation layer 608 separates bottom electrode 104 of device 100 and a plate 610. The overlapping portion of bottom electrode 104 and plate 610 separated by insulation layer 608 form capacitor 506. A via 612 is formed through insulation layer 608 and filled with metal to couple bottom electrode 104 and resistor 508. Plate 610 of capacitor 506 and resistor 508 patterned from a conduction layer 614 and separated by insulation 615. Capacitor 506 and resistor 508 are coupled by a via 616 formed in an insulation layer 618 and filled with metal to be grounded to a substrate 620. The metal in vias 606, 612, and 616 may be aluminum, copper, or another interconnect material.

Various other adaptations and combinations of features of the examples disclosed are within the scope of the invention.

What is claimed is:

1: An integrated circuit, comprising:
a substrate;
semiconductor devices over the substrate, the semiconductor devices including a locally active memristive device operated in a locally reactive domain to exhibit inductor-like behavior.

2: The integrated circuit of claim 1, wherein the inductor-like behavior comprises a phase shift where a voltage across the locally active memristive device leads a current through the locally active memristive device.

3: The integrated circuit of claim 1, wherein the locally active memristive device comprises a negative differential resistance device having an S-shaped current-voltage curve.

4: The integrated circuit of claim 3, wherein the semiconductor devices include other electronic components comprising a circuit to excite the locally active memristive device with a periodic input signal, the periodic input signal comprising a period and a magnitude based on switching times and switching currents of the locally active memristive device, respectively.

5: The integrated circuit of claim 4, wherein:
the periodic input signal comprises a current signal;
the magnitude is within ±10% of a range between a first switching current and a second switching current; and
the period is within a factor of five of a sum of the switching times.

6: The integrated circuit of claim 4, wherein:
the periodic input signal comprises a voltage signal;
the magnitude creates a current through the locally active memristive device having another magnitude within ±10% of a range between a first switching current and a second switching current; and
the period is within a factor of five of a sum of the switching times.

7: The integrated circuit of claim 1, wherein the locally active memristive device comprises a two-terminal metal-insulator-metal device including an insulator comprising a transition metal oxide that exhibits a temperature-driven insulator-to-metal phase transition.

8: The integrated circuit of claim 7, wherein the semiconductor devices include other electronic components comprising a circuit to excite the locally active memristive device with an input signal, the input signal comprising an offset to main the locally active memristive device at the edge of a low resistance state.

9: The integrated circuit of claim 1, wherein the semiconductor devices comprise a filter, an impedance matching network, a phase shifter, or an antenna.

10: A method to operate an integrated circuit including a locally active memristive device, comprising:
operating the locally active memristive device in a locally reactive region of an operating domain where the locally active memristive device exhibits inductor-like behavior.

11: The method of claim 10, wherein the inductor-like behavior comprises a phase shift where a voltage across the locally active memristive device leads a current through the locally active memristive device.

12: The method of claim 10, wherein the locally active memristive device comprises a negative differential resistance device having an S-shaped current-voltage curve.

13: The method of claim 12, wherein operating comprises generating a periodic input signal comprising a period and a magnitude based on switching times and switching currents of the locally active memristive device, respectively.

14: The method of claim 13, wherein:
the periodic input signal comprises a current signal;
the magnitude is within ±10% of a range between a first switching current and a second switching current; and
the period is within a factor of five of a sum of the switching times.

15: The method of claim 13, wherein:
the periodic input signal comprises a voltage signal;
the magnitude creates a current through the locally active memristive device having another magnitude within ±10% of a range between a first switching current and a second switching current; and
the period is within a factor of five of a sum of the switching times.

16: The method of claim 10, wherein the locally active memristive device comprises a two-terminal metal-insulator-metal device including an insulator comprising a transition metal oxide that exhibits a temperature-driven insulator-to-metal phase transition.

17: The method of claim 16, wherein operating comprises generating an input signal comprising an offset to maintain the locally active memristive device at the edge of a low resistance state.
